(19) United States
(12) Patent Application Publication
(10) Pub. No.: US 2025/0337197 A1
(43) Pub. Date: Oct. 30, 2025

(54) CABLE-AUXILIARY DEVICE

(71) Applicant: Nanning FuLian FuGui Precision Industrial Co., Ltd., Nanning (CN)

(72) Inventor: Wu-Jen Lo, New Taipei (TW)

(21) Appl. No.: 18/651,351

(22) Filed: Apr. 30, 2024

(51) Int. Cl. H01R 13/633; H01R 13/502; H01R 13/52; H01R 13/627

(52) U.S. Cl. CPC H01R 13/633; H01R 13/502; H01R 13/5213; H01R 13/6272

(57) ABSTRACT

A cable-auxiliary device includes a housing, a clamp element, and a movement element. The housing includes a first protrusion. The clamp element is movably disposed in the housing, and includes a clamp arm a second protrusion disposed on the clamp arm. The movement element is movably disposed on the housing. The housing is adjacent to an electrical connector, and a plug of a cable is inserted into the electrical connector through the clamp element. The clamp element is moved by pulling the movement element, so that the clamp arm clamps the plug, and pulls the plug from the electrical connector. During the clamp arm clamping the plug, the first protrusion pushes the second protrusion so that the clamp arm clamps the plug.

### FIELD

The subject matter herein generally relates to cable-auxiliary devices, in particular to cable-auxiliary devices that assist in pulling out cables from electrical connectors.

### BACKGROUND

When the network-communication device is installed in an outdoor environment, in order to prevent rain or dust from directly entering the slot of the electrical connector, the electrical connector is disposed inside the casing with a waterproof structure to avoid damage to the electrical connector.

However, the waterproof structure is complex, and another adapter cable needs to be used to connect the electrical connector inside the casing. Therefore, the manufacturing cost of network communication devices with waterproof mechanisms are increased.

### BRIEF DESCRIPTION OF THE DRAWINGS

Many aspects of the present disclosure are better understood with reference to the following drawings. The components in the drawings are not necessarily drawn to scale, the emphasis instead being placed upon clearly illustrating the principles of the present disclosure. It will be appreciated that for simplicity and clarity of illustration, where appropriate, reference numerals have been repeated among the different figures to indicate corresponding or analogous elements.

FIG. 1 is a perspective view of an electronic device, a cable, and a cable-auxiliary device in view of in accordance with an embodiment of the present disclosure.

FIG. 2 is a perspective view of a cable-auxiliary device shown in FIG. 1.

FIG. 3 is an exploded view of the cable-auxiliary device shown in FIG. 2.

FIG. 4 is a partial cross-sectional view of the housing shown in FIG. 2.

FIG. 5A and FIG. 5B are cross-sectional views of the cable-auxiliary device in a first process of using the cable-auxiliary device.

FIG. 6A is a side view of the cable-auxiliary device in a second process of using the cable-auxiliary device.

FIG. 6B is a cross-sectional view of the cable-auxiliary device in the second process of using the cable-auxiliary device.

FIG. 7A is a side view of the cable-auxiliary device in a third process of using the cable-auxiliary device.

FIG. 7B is a cross-sectional view of the cable-auxiliary device in the third process of using the cable-auxiliary device.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The disclosure is illustrated by way of embodiments and not by way of limitation in the figures of the accompanying drawings, in which like references indicate similar elements. It should be noted that references to “an” or “one” embodiment in this disclosure are not necessarily to the same embodiment, and such references mean “at least one.”

The term “connect” is defined as directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series, and the like.

The present disclosure provides a cable-auxiliary device. A cable can be directly inserted into the electrical connector in the casing, and the cable can be pulled out of the electrical connector with the assistance of the cable-auxiliary device without additional adapter cables. Therefore, the manufacturing cost of electronic devices with waterproof mechanisms can be reduced.

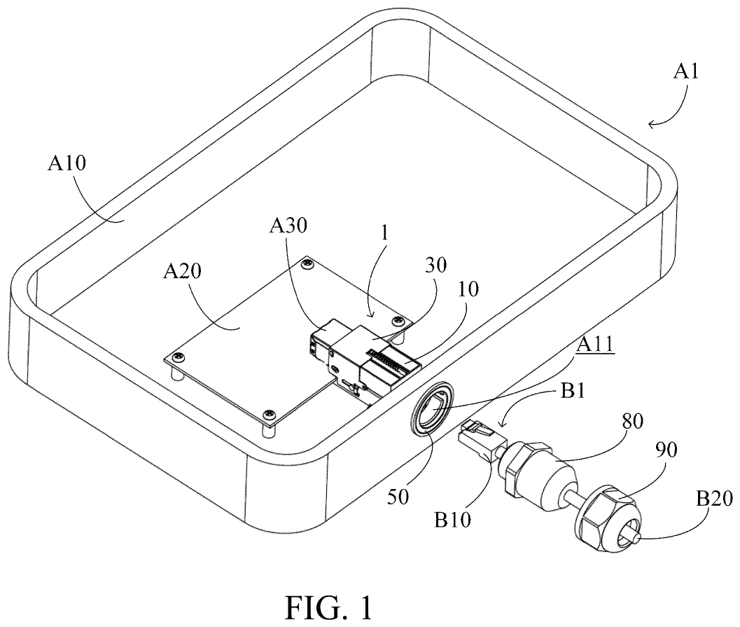

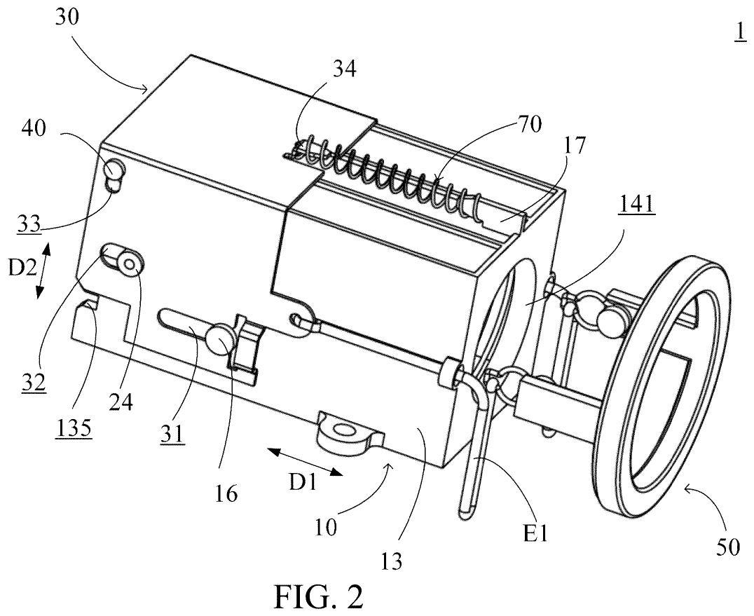

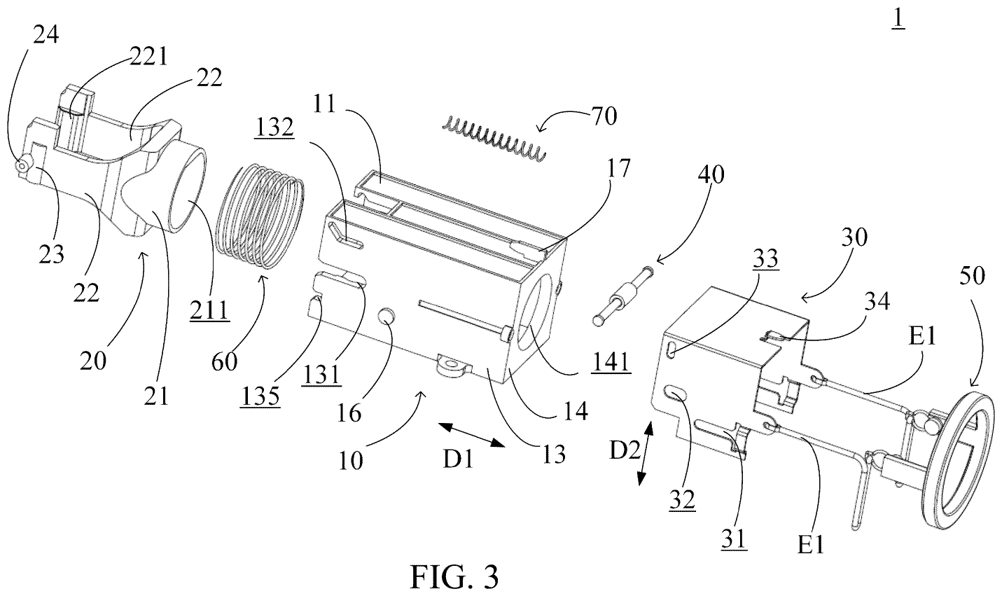

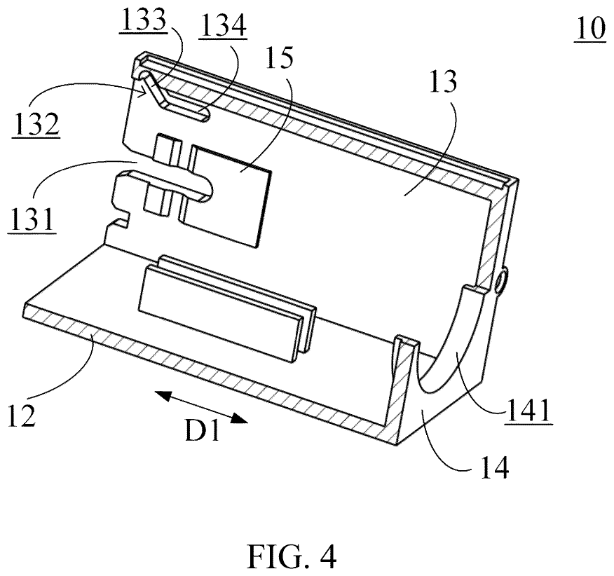

FIG. 1 is a perspective view of an electronic device A1, a cable B1, and a cable-auxiliary device 1 in view of in accordance with an embodiment of the present disclosure. FIG. 2 is a perspective view of a cable-auxiliary device 1 shown in FIG. 1. FIG. 3 is an exploded view of the cable-auxiliary device 1 shown in FIG. 2. FIG. 4 is a partial cross-sectional view of the housing 10 shown in FIG. 2. The electronic device A1 may be a network-communication device, such as a router, a wireless access point, a network switch, a personal computer, a laptop computer, a tablet computer, or a server, etc. In the embodiment, the electronic device A1 includes a waterproof mechanism.

The electronic device A1 includes a casing A10, a circuit board A20 and an electrical connector A30. For the purpose of clarity, the structure of the casing A10 is simplified, and the upper cover of the casing A10 is not shown in FIG. 1. The electronic device A1 may further include electronic components such as a power supply, a processor, a storage device, and a memory, but these are not shown in figures for clarity. The circuit board A20 and the electrical connector A30 are disposed in the casing A10, and the electrical connector A30 is disposed in the circuit board A20. The electrical connector A30 is adjacent to the opening A11 of the casing A10, and is separated from the opening A11. The electrical connector A30 may be a network-communication electrical connector A30. In the embodiment, the electrical connector A30 may be a RJ45 socket, but it is not limited thereto.

The cable B1 includes a plug B10 and a signal wire B20. The plug B10 is connected to the signal wire B20. In the embodiment, the plug B10 may be a RJ45 plug. The cable-auxiliary device 1 is disposed in the electronic device A1, and located between the opening A11 and the electrical connector A30. The plug B10 be inserted into the electrical connector A30 through the opening A11 of housing 10 and the cable-auxiliary device 1. Since the electrical connector A30 is separated from the opening A11, the cable-auxiliary device 1 can assist the user to accurately insert plug B10 into the electrical connector A30. Moreover, the cable-auxiliary device 1 can assist the user to separate the plug B10 from the electrical connector A30.

The cable-auxiliary device 1 includes a housing 10, a clamp element 20, a movement element 30, a latch 40, a ring 50, a main elastic element 60, and an outer elastic element 70. The housing 10 may be a hollow structure, and extend in the movement direction D1. The housing 10 is adjacent to the electrical connector A30. The housing 10 includes a top plate 11, a bottom plate 12, two side walls 13, a front wall 14, two first protrusions 15, and two limit bumps 16. The top plate 11 is parallel to the bottom plate 12, and is separated from the bottom plate 12. The side walls 13 are perpendicular to the top plate 11 and the bottom plate 12. The side walls 13 are parallel to each other, and separated from each other. The top plate 11, the bottom plate 12, and the side walls 13 extends in the movement direction D1. The front wall 14 is connected to edges of the top plate 11, the bottom plate 12, and the side walls 13. The front wall 14 extends perpendicular to the movement direction D1.

Each side wall 13 has a first position groove 131 and a first guide groove 132. The first position groove 131 extends in the movement direction D1. The first guide groove 132 is located above the first position groove 131. The front wall 14 has a front opening 141. The first protrusions 15 are in the housing 10, and are respectively disposed on the inner sides of the side walls 13. One first protrusion 15 faces another first protrusion 15. Moreover, two limit bumps 16 are respectively disposed on outer sides of the side walls 13. In the embodiment, each side wall 13 has a connection groove 135. The circuit board A20 can be inserted in the connection groove 135, and fastened to the housing 10.

The clamp element 20 is movably disposed in the housing 10. The plug B10 of the cable B1 is plugged into the electrical connector A30 through the clamp element 20. In the embodiment, the clamp element 20 is movably in the movement direction D1 relative to the housing 10. The clamp element 20 includes a base 21, two clamp arms 22, two second protrusions 23, and two position posts 24. The base 21 has a channel 211 extending in the movement direction D1, and the channel 211 runs through the base 21. The plug B10 can be inserted into the electrical connector A30 through the channel 211. When the clamp element 20 is moved to a clamping position, the base 21 contacts the front wall 14, and the channel 211 is in communication with the front opening 141. Two clamp arms 22 are connected to the base 21, and extend in the movement direction D1. Two clamp arms 22 are parallel to each other, and separated from each other. Two second protrusions 23 are respectively disposed on the outer sides and free ends of the clamp arms 22. In the embodiment, the clamp arms 22 are moved toward the plug B10 and clamp the plug B10 by the first protrusions 15 of the housing 10 push the second protrusions 23.

In the embodiment, each clamp arm 22 includes a clamp bump 221, located at the inner side and the free end of the clamp arm 22. The clamp bumps 221 face a central axis of the clamp element 20. One clamp bump 221 faces another clamp bump 221. Two clamp arms 22 are moved toward the central axis of the clamp element 20, so that the clamp bumps 221 clamp the plug B10. The central axis extends in the movement direction D1.

The two position posts 24 are respectively connected to the two clamping arms 22, and extend through the first position groove 131 of the housing 10. Therefore, the position posts 24 constrain the clamp element 20 to move in the movement direction D1 relative to the housing 10.

The movement element 30 is movably disposed on the housing 10, and the movement element 30 is movably in the movement direction D1 relative to the housing 10. The movement element 30 is pulled to move the clamp element 20, so that the clamp arm 22 clamps the plug B10, and pulls the plug B10 out of the electrical connector A30.

In the embodiment, the movement element 30 may be a U-shaped structure, covers the top plate 11 and the side walls 13 of the housing 10. The movement element 30 includes two limit grooves 31, two second position grooves 32, and two second guide grooves 33. The limit groove 31 extends the movement direction D1. The limit bumps 16 of the housing 10 are respectively in the limit grooves 31 of the movement element 30. Therefore, the limit bumps 16 constrain the movement element 30 to move in the movement direction D1 relative to the housing 10. The second position groove 32 extends in the movement direction D1, and the second guide groove 33 extends in the vertical direction D2. The vertical direction D2 is perpendicular to the movement direction D1.

The position posts 24 are further located within the second position grooves 32 of the movement element 30. The position posts 24 constrain the clamp element 20 and the movement element 30 to move in the movement direction D1 relative to the housing 10. In the embodiment, the length of the first position grooves 131 are greater than the length of the second position grooves 32. The length of the first position grooves 131 and the length of the second position grooves 32 are measured in the movement direction D1.

The latch 40 is movably disposed in the housing 10, and is used to engage the plug B10 inserted in the electrical connector A30. The latch 40 extends perpendicular to the movement direction D1. Two ends of the latch 40 are respectively in the first guide grooves 132 of the housing 10 and the second guide grooves 33 of the movement element 30. In the embodiment, each first guide groove 132 includes a first section 133 and a second section 134. The first section 133 is inclined relative to the second section 134. The second section 134 is connected to the first section 133, and extends in the movement direction D1. Moreover, the second guide groove 33 extends in the vertical direction D2. Therefore, when the movement element 30 is moved relative to the housing 10, the latch 40 can be moved in the movement direction D1 and/or the vertical direction D2 by the first guide groove 132 and the second guide groove 33.

The ring 50 is connected to the movement element 30 by ropes E1. The ring 50 is removably mounted on the opening A11 of the casing A10. The plug B10 can be inserted into the electrical connector A30 through the ring 50 and the clamp element 20. When the ring 50 is separated from the casing A10, the ring 50 is located outside the casing A10. At this time, the movement element 30 can be moved in the movement direction D1 by pulling the ring 50.

Two ends of the main elastic element 60 are connected to the housing 10 and the clamp element 20. The main elastic element 60 provides a pushing force to maintain the clamp element 20 in an initial position. In the embodiment, the main elastic element 60 may be a spring. The main elastic element 60 is in the housing 10, and the main elastic element 60 abuts the front wall 14 of the housing 10 and the base 21.

Two ends of the outer elastic element 70 are connected to the housing 10 and the movement element 30. The outer elastic element 70 provides a pulling force to maintain the movement element 30 in an initial position. In the embodiment, the outer elastic element 70 may be a spring. The housing 10 is further includes a first hook 17 disposed on the top plate 11, and adjacent to the front wall 14. The movement element 30 further includes a second hook 34. Two ends of the outer elastic element 70 are respectively connected to the first hook 17 and the second hook 34.

In the embodiment, the cable-auxiliary device 1 further includes a first waterproof cover 80 and a second waterproof cover 90. The first waterproof cover 80 is mounted on the opening A11 of the casing A10, and covers the ring 50 mounted on the opening A11. The second waterproof cover 90 is mounted on the first waterproof cover 80. The cable B1 inserted into the electrical connector extends through the first waterproof cover 80 and the second waterproof cover 90. The first waterproof cover 80 and the second waterproof cover 90 can prevent liquid, such as water, from flowing into the casing A10 through the opening A11.

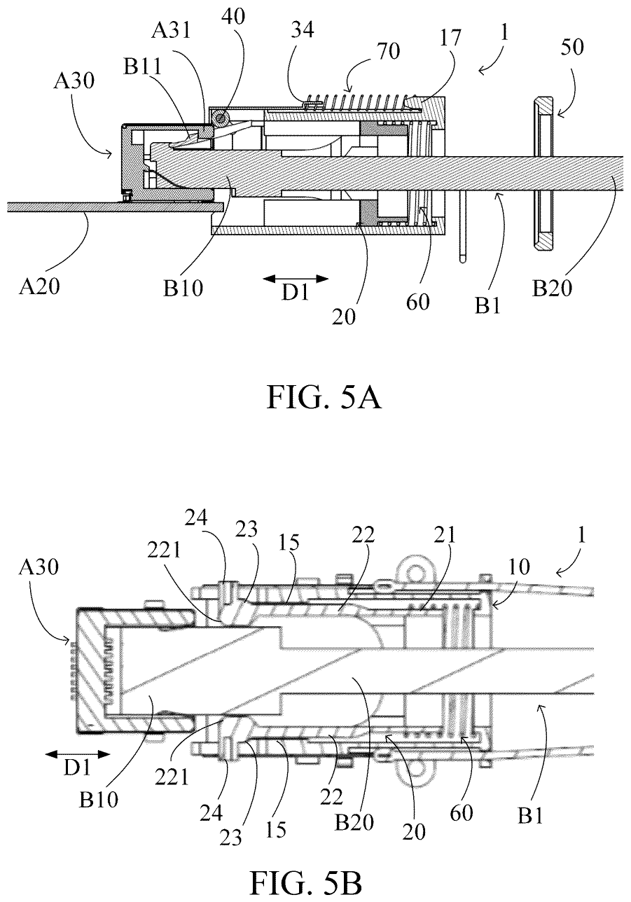

FIG. 5A and FIG. 5B are cross-sectional views of the cable-auxiliary device 1 in a first process of using the cable-auxiliary device 1. As shown in FIG. 2, FIG. 5A and FIG. 5B, the movement element 30 and the clamp element 20 are in an initial position, the ring 50 is mounted in the opening A11 of the casing A10 shown in FIG. 1. The plug B10 is inserted into the electrical connector A30 within the housing 10, and is electrically connected to the electrical connector A30. Moreover, the signal wire B20 extends through the ring 50.

The latch 40 is located at the upper end of the first section 133 of the first guide groove 132, and at the upper end of the second guide groove 33. The block A31 of the electrical connector A30 is engaged with the buckle B11 of the plug B10. The latch 40 is above the buckle B11. Moreover, the position post 24 is in the first end of the second position groove 32. In the embodiment, the first end of the second position groove 32 is closer to the front opening 141 of the front wall 14 than the second end of the second position groove 32. The second protrusion 23 contacts the side wall 10 of the housing 10. In other words, the first protrusion 15 of the housing 10 does not abut the second protrusion 23, and does not push the second protrusion 23 to move.

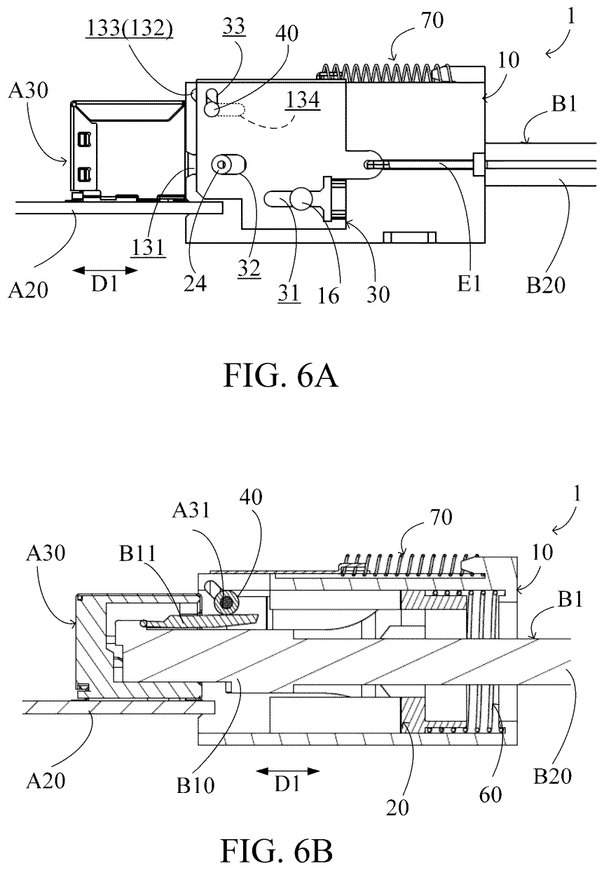

FIG. 6A is a side view of the cable-auxiliary device 1 in a second process of using the cable-auxiliary device 1. FIG. 6B is a cross-sectional view of the cable-auxiliary device 1 in the second process of using the cable-auxiliary device 1. As shown in FIG. 6A and FIG. 6B, the movement element 30 is in a release position, and the clamp element 20 is maintained to the initial position. One user can separate the ring 50 from the opening A11 of the casing A10, and pull the ring 50, such that the ring 50 pulls the movement element 30 to move from the initial position to the release position. The position post 24 is moved from the first end of the second position groove 32 to the second end of the second position groove 32. At this time, the movement element 30 does not move the clamp element 20.

When the movement element 30 is moved from the initial position to the release position in the movement direction D1, the movement element 30 moves the latch 40 in the second guide groove 33 from the upper end of the first section 133 of the first guide groove 132 to the lower end of the first section 133, and the latch 40 is moved from the upper end of the second guide groove 33 to the lower end of the second guide groove 33 due to the inclined first section 133. In other words, when the movement element 30 is in the release position, the latch 40 is in the lower end of the first section 133 of the first guide groove 132, and in the lower end of the second guide groove 33. The latch 40 is diagonally moved in the movement direction D1 and the vertical direction D2 and pushes the buckle B11 of the plug B10, such that the buckle B11 of the plug B10 detaches from the block A31 of the electrical connector A30.

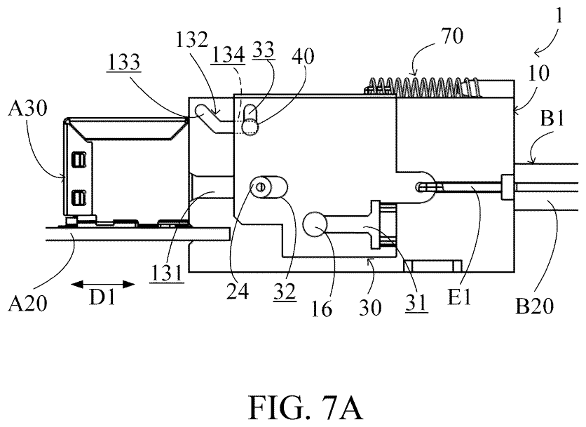

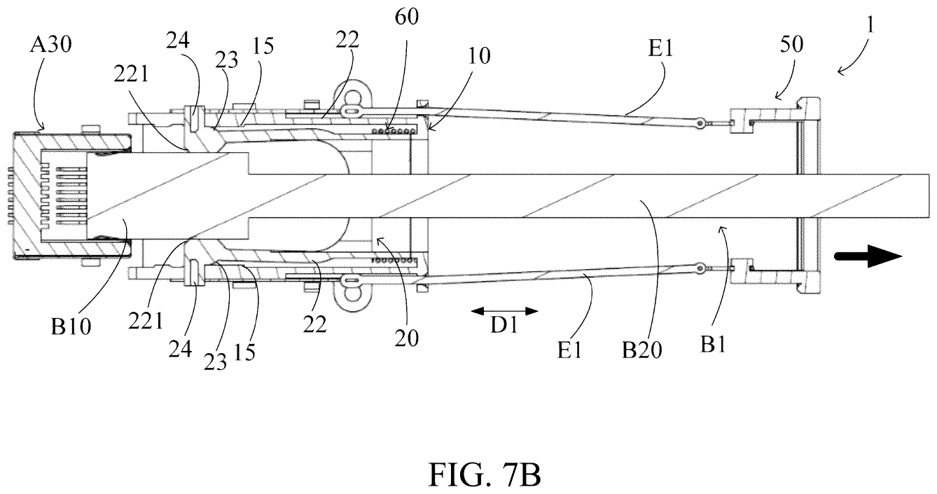

FIG. 7A is a side view of the cable-auxiliary device 1 in a third process of using the cable-auxiliary device 1. FIG. 7B is a cross-sectional view of the cable-auxiliary device 1 in the third process of using the cable-auxiliary device 1. As shown in FIG. 7A and FIG. 7B, the movement element 30 and the clamp element 20 are in a clamping position. The ring 50 pulls the movement element 30 from the release position to a clamping position by continuously pulling the ring 50. At this time the movement element 30 moves the position post 24 at the second end of the second position groove 32, such that the clamp element 20 is moved to the clamping position in the movement direction D1. At this time, the latch 40 is moved to an end of the second section 134 of the second guide groove 33.

When the movement element 30 is moved from the release position to the clamping position in the movement direction D1, the clamp element 20 is moved in the movement direction D1, such that the second protrusion 23 abuts the first protrusion 15 in a direction perpendicular to movement direction D1. In other words, during the clamp arm 22 clamping the plug B10, the first protrusions 15 push the second protrusions 23, such that the plug B10 is clamped by the clamp arm 22.

After the clamp arms 22 clamp the plug B10, the user continues to pull the ring 50 to move the clamp element 20, such that the plug B10 clamp by the clamp element 20 can be moved out relative to the electrical connector A30. Afterward, the user releases the ring, and then the main elastic element 60 and the outer elastic element 70 return the movement element 30 and the clamp element 20 to the initial position. The user can remove the plug B10 from the electrical connector A30 and the casing A10.

In the embodiment, the cable-auxiliary device 1 of the present disclosure assists the cable B1 to be directly inserted into the electrical connector A30 within the casing A10, and assists the cable B1 to be pulled out from the electrical connector A30. By utilizing the cable-auxiliary device 1 of the present disclosure, there is no need to use an adapter cable to connect the electrical connector A30 within the casing A10. Therefore, the manufacturing cost of electronic devices with waterproof mechanisms can be reduced.

Many details are often found in the relevant art, thus many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will, therefore, be appreciated that the embodiments described above may be modified within the scope of the claims.

What is claimed is:

1. A cable-auxiliary device, comprising:
a housing comprising a first protrusion;
a clamp element movably disposed in the housing, and comprising a clamp arm and a second protrusion disposed on the clamp arm; and
a movement element movably disposed on the housing,
wherein the housing is adjacent to an electrical connector, and a plug of a cable is inserted into the electrical connector through the clamp element,
the clamp element is moved by pulling the movement element, such that the clamp arm clamps the plug, and pulls the plug from the electrical connector,
wherein as the clamp arm clamps on the plug, the first protrusion pushes the second protrusion until the clamp arm clamps the plug.

2. The cable-auxiliary device as claimed in claim 1, further comprising:
a ring connected to the movement element by a rope, the plug is inserted into the electrical connector through the clamp element and the ring.

3. The cable-auxiliary device as claimed in claim 2, wherein the housing and the electrical connector are disposed in a casing, the casing comprises an opening, and the ring is removably mounted on the opening.

4. The cable-auxiliary device as claimed in claim 3, further comprising:
a first waterproof cover mounted on the opening, the first waterproof cover covering the ring, and the cable extending through the first waterproof cove.

5. The cable-auxiliary device as claimed in claim 4, further comprising:
a second waterproof cover mounted on the first waterproof cover, and the cable further extending through the second waterproof cover.

6. The cable-auxiliary device as claimed in claim 1, further comprising:
a latch movably disposed in a first guide groove of the housing and a second guide groove of the movement element,
wherein the latch is configured to engage the plug which is inserted into the electrical connector.

7. The cable-auxiliary device as claimed in claim 6, wherein the first guide groove comprises a first section and a second section, the first section is inclined relative to the second section, the second section is connected to the first section, and extends in a movement direction, the second guide groove extends in a vertical direction, perpendicular to the movement direction.

8. The cable-auxiliary device as claimed in claim 7, wherein the latch extends perpendicular to the vertical direction and the movement direction.

9. The cable-auxiliary device as claimed in claim 7, wherein when the clamp element and the movement element are in an initial position, the latch is in the first section of the first guide groove, and an upper end of the second guide groove.

10. The cable-auxiliary device as claimed in claim 7, wherein when the clamp element and the movement element are in a clamping position, the latch is in the second section of the first guide groove, and a lower end of the second guide groove.

11. The cable-auxiliary device as claimed in claim 1, wherein the clamp element further comprises a position post connected to the clamp arm, and the position post extends through a first position groove of the housing, and is located in a second position groove of the movement element.

12. The cable-auxiliary device as claimed in claim 11, wherein the first position groove and the second position groove extend in a movement direction, a length of the first position groove is greater than a length of the second position groove,
wherein the length of the first position groove and the length of the second position groove are measured in the movement direction.

13. The cable-auxiliary device as claimed in claim 1, wherein the housing further comprises a limit bump located in a limit groove of the movement element, the limit groove extends in a movement direction, and the limit bump constrains the movement element to move in the movement direction relative to the housing.

14. The cable-auxiliary device as claimed in claim 1, further comprising:
a main elastic element connected to the housing and the clamp element, so as to maintain the clamp element in an initial position.

15. The cable-auxiliary device as claimed in claim 1, further comprising:
an outer elastic element connected to the housing and the movement element, so as to maintain the clamp element in an initial position.
